(19) United States
(12) Patent Application Publication
(10) Pub. No.: US 2007/0197008 A1
(43) Pub. Date: Aug. 23, 2007

(54) MIRROR-LIKE INPUT KEY

(75) Inventor: JEN-YU LIANG, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,719

(22) Filed: Sep. 15, 2006

(30) Foreign Application Priority Data
Feb. 23, 2006 (CN) 200610033921.3

(51) Int. Cl. H01L 21/28

(52) U.S. Cl. 438/570

(57) ABSTRACT

A mirror-like key (40) comprises a base portion (46), a sputtered layer (44) and a lightproof printed layer (42) with a light-pervious label (422). The base portion comprises an upper surface (462) and a lower surface (464) opposite to the upper surface. The sputtered layer is formed on one of the upper surface and the lower surface of the base portion. The printed layer is formed below the sputtered layer.

### 1. FIELD OF THE INVENTION

The present invention pertains to mirror-like input keys, and particularly to a mirror-like key which is pervious to light.

### 2. DESCRIPTION OF RELATED ART

Nowadays, transparent keys are widely used in various electronic devices with a light source for increasing visibility of keys in a dim or dark environment. One type of the keys has mirror-like surfaces for aesthetic appearance. During manufacturing, shallow engraved labels representing the functions of the keys are often formed on the surfaces of the keys by laser marking. However, the conventional mirror-like surfaces of the keys manufactured by such manner may typically be uneven and imperfect, and even lose the original aesthetic appearance thereof.

Therefore, a heretofore unaddressed need exists in the industry to overcome the aforementioned deficiencies and inadequacies.

### SUMMARY OF THE INVENTION

In an exemplary embodiment, a mirror-like key, comprises a base portion, a sputtered layer, and a lightproof printed layer with a light-pervious label. The base portion comprises an upper surface and a lower surface opposite to the upper surface. The sputtered layer is formed on one of the upper surface and the lower surface of the base portion. The printed layer is formed below the sputtered layer.

Other advantages and novel features will become more apparent from the following detailed description when taken in conjunction with the accompanying drawings, in which:

### BRIEF DESCRIPTION OF THE DRAWINGS

FIG. 1 is a perspective view of a mirror-like key of an exemplary embodiment of the present invention;

FIG. 2A is a plan view of the mirror-like key of FIG. 1 without a light source;

FIG. 2B is a plan view of the mirror-like key of FIG. 1 with the light source; and

FIG. 3 is a perspective view of a mirror-like key of another exemplary embodiment of the present invention.

### DETAILED DESCRIPTION OF THE INVENTION

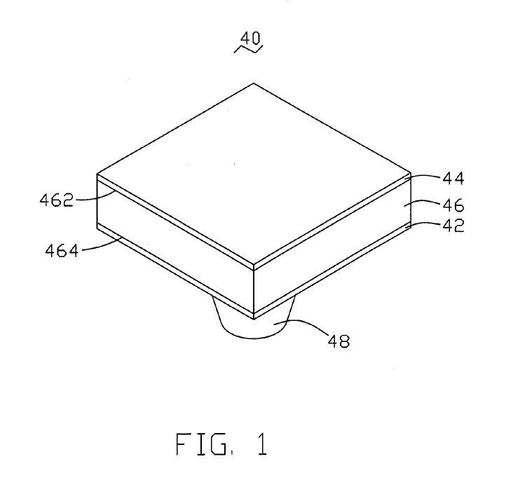

Referring to FIG. 1, a mirror-like key 40 of an exemplary embodiment of the present invention is shown. The mirror-like key 40 comprises a base portion 46, a sputtered layer 44, and a printed layer 42.

The base portion 46, comprising light-pervious materials such as plastic pervious to light, comprises an upper surface 462 and a lower surface 464 opposite to the upper surface 462. The sputtered layer 44 is formed by sputter deposition performed on the upper surface 462 of the base portion 46, and light transmission of the sputtered layer 44 is limited to between 10% and 20%. The sputtered layer 44 is mirror-like and pervious to light. The printed layer 42 is a lightproof ink layer with a light-pervious label 422, and is printed on the lower surface 464 of the base portion 46. In the exemplary embodiment, the light-pervious label 422 can be an engraved symbol or character used as an indicator of the key 40. A light-pervious projecting block 48 is affixed on the printed layer 42 and corresponds to a trigger on a circuit board (not shown). In the exemplary embodiment, the projecting block 48 comprises silicon rubber.

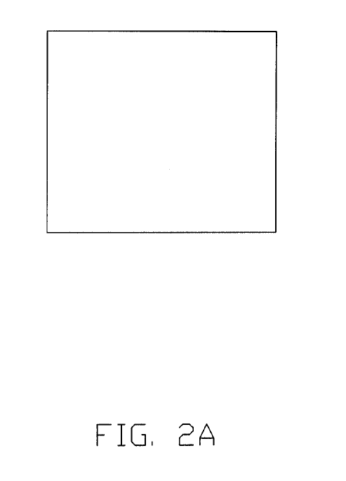

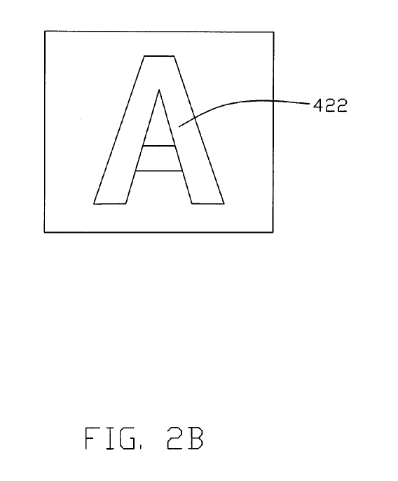

Referring to FIG. 2A, during use, when there is no light source or a light source (not shown) disposed under the mirror-like key 40 is not turned on, the upper surface of the mirror-like key 40 is mirrorlike with smooth and aesthetic appearance.

Referring to FIG. 2B, when a light source is disposed under the mirror-like key 40 and turned on, an image of the label 422 can be seen through the sputtered layer 44.

Because the sputtered layer 44 is positioned above the printed layer 42, an integrated mirror-like surface can be seen from above the mirror-like key 40 without an additional light source disposed under the mirror-like key 40. Since the printed layer 42 is positioned on the lower surface 464 of the base portion 46 and the projecting block 48 is affixed on the surface of the printed layer 42, the printed layer 42 is protected from abrasion during use.

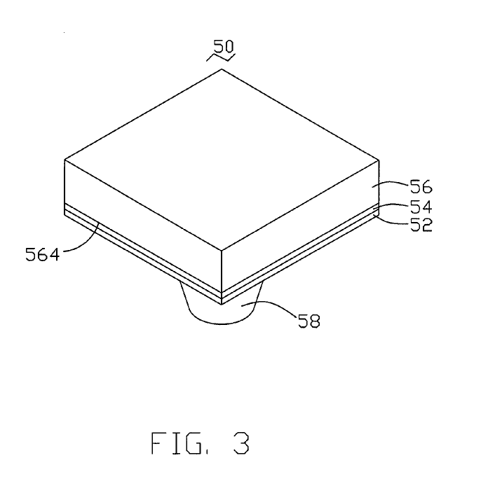

Referring to FIG. 3, a mirror-like key 50 of another exemplary embodiment of the present invention is shown. The mirror-like key 50 comprises a base portion 56, a sputtered layer 54 and a printed layer 52. All elements, constructions, and functions of the exemplary embodiment are the same as the foregoing exemplary embodiment, except that the sputtered layer 54 is positioned on a lower surface 564 of the base portion 56, and the printed layer 52 is printed on a surface of the sputtered layer 54.

While exemplary embodiments have been described above, it should be understood that they have been presented by way of example only and not by way of limitation. Thus the breadth and scope of the present invention should not be limited by the above-described exemplary embodiments, but should be defined only in accordance with the following claims and their equivalents.

What is claimed is:

1. A mirror-like key, comprising:
a base portion, comprising an upper surface and a lower surface opposite to the upper surface;
a light-pervious sputtered layer, formed on one of the upper surface and the lower surface of the base portion; and
a lightproof printed layer with a light-pervious label, formed below the sputtered layer.

2. The mirror-like key as claimed in claim 1, wherein the base portion comprises light-pervious materials.

3. The mirror-like key as claimed in claim 1, wherein a light-pervious projecting block is affixed on a lower surface of the printed layer.

4. The mirror-like key as claimed in claim 1, wherein a light transmission of the sputtered layer is limited between 10% and 20%.

5. The mirror-like key as claimed in claim 1, wherein when the sputtered layer is formed on the upper surface of the base portion, and the printed layer is formed on the lower surface of the base portion.

6. The mirror-like key as claimed in claim 1, wherein when the sputtered layer is formed on the lower surface of the base portion, the printed layer is printed on a surface of the sputtered layer.

7. A mirror-like key, comprising:
a base portion, comprising an upper surface and a lower surface opposite to the upper surface;
a light-pervious sputtered layer, formed on one of the upper surface and the lower surface of the base portion; and
a label, showing function of the key, formed below the sputtered layer.

8. The mirror-like key as claimed in claim 7, wherein the base portion comprises light-pervious materials.

9. The mirror-like key as claimed in claim 7, wherein the label is pervious to light.

10. The mirror-like key as claimed in claim 7, wherein a light-pervious projecting block is affixed on a lower surface of the printed layer.

11. The mirror-like key as claimed in claim 7, wherein a light transmission of the sputtered layer is limited to between 10% and 20%.

12. The mirror-like key as claimed in claim 7, wherein when the sputtered layer is formed on the upper surface of the base portion, and the label is formed on the lower surface of the base portion.

13. The mirror-like key as claimed in claim 7, wherein when the sputtered layer is formed on the lower surface of the base portion, the label is formed on a surface of the sputtered layer.

14. A key assembly comprising:
a base portion of the key assembly made of light-pervious material;
a first layer attachably formed beside the base portion by means of sputtering the layer onto the base portion, the first layer made of material being light-pervious and mirror-like-effect generable for the key assembly; and
a second layer discretely formed from the first layer and attachably formed beside the base portion, the second layer made of lightproof material and forming a light-pervious label therein in order to show the label under light illumination as an indicator of the key assembly.

15. The key assembly as claimed in claim 14, wherein the second layer is attachably formed beside the base portion neighboring the first layer.

16. The key assembly as claimed in claim 14, wherein the second layer is attachably formed beside the base portion opposite to the first layer.
